(19) United States
(12) Patent Application Publication
(10) Pub. No.: US 2012/0048330 A1
(43) Pub. Date: Mar. 1, 2012

(54) THIN FILM SOLAR CELL MODULE AND FABRICATING METHOD THEREOF

(75) Inventors: Jeonghun SON, Seoul (KR); Heonmin Lee, Seoul (KR); Jinhyung Ahn, Seoul (KR); Byungki Yang, Seoul (KR); Sungeun Lee, Seoul (KR); Youngjoo Eo, Seoul (KR)

(73) Assignee: LG ELECTRONICS INC., Seoul (KR)

(21) Appl. No.: 13/174,445

(22) Filed: Jun. 30, 2011

(30) Foreign Application Priority Data
Nov. 4, 2010 (KR) 10-2010-0109373

(51) Int. Cl. H01L 31/042; H01L 31/0224

(52) U.S. Cl. 136/244; 438/69; 257/E31.126; 257/E31.127

(57) ABSTRACT

Discussed herein are a thin film solar cell module and a fabricating method thereof. The solar cell module includes photoelectric conversion layers on the transparent electrode layer and including at least a first photoelectric conversion layer, a second photoelectric conversion layer and a third photoelectric conversion layer, the photoelectric conversion layers further including at least one of a first intermediate layer between the first and second photoelectric conversion layers, cut by first cutting grooves, and a second intermediate layer between the second and third photoelectric conversion layers, cut by second cutting grooves, the first intermediate layer and the second intermediate layer are respectively formed of a transparent conductive oxide (TCO). Thereby, internal shorts are prevented and and fill factor reduction due to shunt resistance generated during a scribing process is reduced or prevented.

### CROSS-REFERENCE TO RELATED APPLICATION

This application claims priority to and the benefit of Korean Patent Application No. 10-2010-0109373, filed on Nov. 4, 2010, in the Korean Intellectual Property Office, the disclosure of which is incorporated herein by reference.

### BACKGROUND OF THE INVENTION

1. Field of the Invention

Embodiments of the present invention relate to a thin film solar cell module and a fabricating method thereof.

2. Description of the Related Art

Recently, as conventional energy resources, such as oil or coal, are expected to be depleted, interest in new alternative energy sources has risen. Among alternative energy sources, solar cells are a focus of attention as next generation devices to directly convert sunlight energy into electrical energy using semiconductor elements.

Solar cells generally use P-N junctions, and are variously classified into single crystalline silicon solar cells, polycrystalline silicon solar cells, amorphous silicon solar cells, compound solar cells, dye-sensitized solar cells and so on according to materials thereof so as to achieve improvement in efficiency and characteristics. Among solar cells, the widely used crystalline silicon solar cells have high material costs with respect to power generation efficiency and are manufactured through a complicated process. In order to solve these problems, interest has risen in thin film solar cells in which silicon is deposited to a thin thickness on a surface of an inexpensive glass or plastic substrate.

Nevertheless, the thin film solar cells have lower photoelectric conversion efficiency than the silicon solar cells. Thus, a tandem structure or a triple structure in which photoelectric conversion layers having silicon of different crystallinities being vertically arranged has been researched, and an intermediate layer reflecting incident light is interposed between the respective photoelectric conversion layers so as to maximize photoelectric conversion efficiency.

However, in such a structure, photoelectric conversion efficiency may be lowered due to defects, such as internal shorts occurring when the intermediate layer and a rear electrode come into electrical contact with each other.

Further, when scribing processes to form a solar cell module are carried out, removed conductive materials (for example, materials of a TCO-based intermediate layer) may be re-deposited on the side surfaces of the photoelectric conversion layers, thus forming a shunt resistance path, i.e., an unnecessary current path, thereby reducing a fill factor and thus lowering power generation efficiency.

### SUMMARY OF THE INVENTION

An object of the present invention is to provide a thin film solar cell module which reduces or prevents a lowering of power generation efficiency and a fabricating method thereof.

To achieve the above objects, there is provided a thin film solar cell module according to an example embodiment of the present invention, including a front substrate, a transparent electrode layer patterned on the front substrate to have at least first transparent electrodes and second transparent electrodes, photoelectric conversion layers provided on the transparent electrode layer and including at least a first photoelectric conversion layer, a second photoelectric conversion layer and a third photoelectric conversion layer, and a rear electrode provided on the photoelectric conversion layers, wherein the photoelectric conversion layers further include at least one of a first intermediate layer provided between the first photoelectric conversion layer and the second photoelectric conversion layer, cut by first cutting grooves, and a second intermediate layer provided between the second photoelectric conversion layer and the third photoelectric conversion layer, cut by second cutting grooves, and the first intermediate layer and the second intermediate layer are respectively formed of a transparent conductive oxide (TCO).

The first cutting grooves and the second cutting grooves may be extended to an upper surface of the transparent electrode layer at different positions in the photoelectric conversion layers, the second photoelectric conversion layer may fill the first cutting grooves, and the third photoelectric conversion layer may fill the second cutting grooves.

The third photoelectric conversion layer may be cut by third cutting grooves extended to the upper surface of the transparent electrode layer at positions differing from the first cutting grooves and the second cutting grooves in the photoelectric conversion layers, and the rear electrode may fill the third cutting grooves so as to be connected to the transparent electrode layer.

The rear electrode may be cut by fourth cutting grooves at positions differing from the first cutting grooves to the third cutting grooves in the photoelectric conversion layers, and the fourth cutting grooves may be extended to the upper surface of the transparent electrode layer so as to form an insulating layer.

To achieve the above objects, there is provided a fabricating method of a thin film solar cell module according to an example embodiment of the present invention, including forming a transparent electrode layer on a substrate and then patterning the transparent electrode layer to have at least first transparent electrodes and second transparent electrodes, forming photoelectric conversion layers, including at least a first photoelectric conversion layer, a second photoelectric conversion layer and a third photoelectric conversion layer, on the first transparent electrodes and the second transparent electrodes and then patterning the photoelectric conversion layers, and forming a rear electrode on the photoelectric conversion layers and then patterning the rear electrode, wherein the forming and patterning of the photoelectric conversion layers include at least one of forming first cutting grooves by forming a first intermediate layer on the first photoelectric conversion layer and then patterning the first intermediate layer and forming second cutting grooves by forming a second intermediate layer on the second photoelectric conversion layer and then patterning the second intermediate layer, the first intermediate layer and the second intermediate layer are respectively formed of a transparent conductive oxide (TCO), and the first cutting grooves and the second cutting grooves are extended to an upper surface of the second transparent electrodes at different positions in the photoelectric conversion layers.

The forming and patterning of the photoelectric conversion layers may further include forming third cutting grooves by patterning the third photoelectric conversion layer, and the first cutting grooves, the second cutting grooves and the third cutting grooves may be extended to the upper surface of the second transparent electrodes at different positions in the photoelectric conversion layers.

To achieve the above objects, there is provided a thin film solar cell module according to an example embodiment of the present invention, including a front substrate, a transparent electrode layer patterned on the front substrate, photoelectric conversion layers provided on the transparent electrode layer, and including at least a first photoelectric conversion layer, a second photoelectric conversion layer and a third photoelectric conversion layer, cutting grooves formed entirely through the photoelectric conversion layers and extending to an upper surface of the transparent electrode layer to divide the photoelectric conversion layers, and a rear electrode provided on the upper surface of the photoelectric conversion layers so as to fill the cutting grooves.

The photoelectric conversion layers further include at least one of a first intermediate layer provided between the first photoelectric conversion layer and the second photoelectric conversion layer, and a second intermediate layer provided between the second photoelectric conversion layer and the third photoelectric conversion layer, and the first intermediate layer and the second intermediate layer include silicon oxide (SiOₓ).

The first photoelectric conversion layer may be formed of amorphous silicon (a-Si), the second photoelectric conversion layer may be formed of amorphous silicon-germanium (a-Si:Ge), and the third photoelectric conversion layer may be formed of microcrystalline silicon (μc-Si) or microcrystalline silicon-germanium (μc-Si:Ge). Further, the first intermediate layer may be formed of amorphous silicon oxide and the second intermediate layer may be formed of amorphous silicon oxide doped with germanium.

The first intermediate layer and the second intermediate layer may be doped with impurities.

### BRIEF DESCRIPTION OF THE DRAWINGS

The above and other objects, features and other advantages of the embodiments of the present invention will be more clearly understood from the following detailed description taken in conjunction with the accompanying drawings, in which:

FIG. 1 is a cross-sectional view of a thin film solar cell module in accordance with one embodiment of the present invention;

FIGS. 2 to 9 are views illustrating a fabricating process of the thin film solar cell module of FIG. 1;

FIG. 10 is a cross-sectional view of a thin film solar cell module in accordance with another embodiment of the present invention; and

FIG. 11 is a cross-sectional view of a thin film solar cell module in accordance with yet another embodiment of the present invention.

### DETAILED DESCRIPTION OF THE EMBODIMENTS

Reference will now be made in detail to example embodiments of the present invention, examples of which are illustrated in the accompanying drawings. Wherever possible, the same reference numbers will be used throughout the drawings to refer to the same or like parts.

Prior to description of the embodiments, it will be understood that when elements are referred to as being “on” or “under” other elements, they can be directly or indirectly on or under the other elements. Position relations between respective elements are illustrated based on the accompanying drawings. Further, in the drawings, the thicknesses or sizes of the respective elements are exaggerated, omitted, or schematically illustrated for convenience and clarity of description. Therefore, the sizes or areas of the respective elements do not denote the actual sizes or areas thereof.

Hereinafter, the embodiments of the present invention will be described with reference to the accompanying drawings.

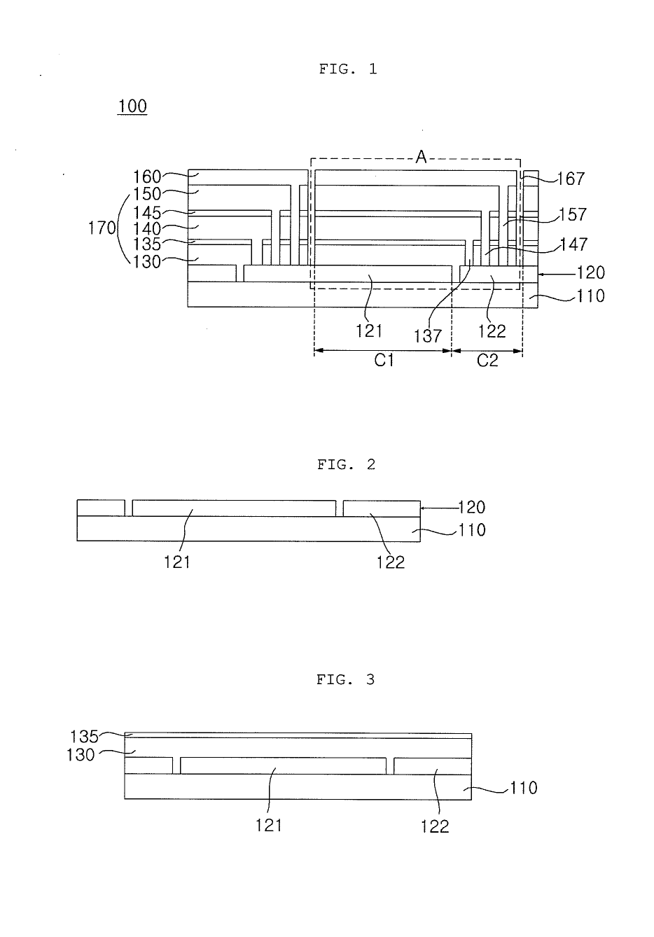

FIG. 1 is a cross-sectional view of a thin film solar cell module in accordance with one embodiment of the present invention.

With reference to FIG. 1, a thin film solar cell module 100 in accordance with an embodiment of the present invention includes a front substrate 110 upon which sunlight is incident, a transparent electrode layer 120 patterned on the front substrate 110, photoelectric conversion layers 170 located on the transparent electrode layer 120 and including at least a first photoelectric conversion layer 130, a second photoelectric conversion layer 140 and a third photoelectric conversion layer 150, and a rear electrode 160 provided on the photoelectric conversion layers 170.

The substrate 110 may be formed of a transparent material, such as glass or a polymer so as to transmit light.

The transparent electrode layer 120 may be formed of at least one selected from among metal oxides, for example, tin oxide (SnO₂), zinc oxide (ZnO) and indium tin oxide (ITO), or may be formed of a mixture obtained by mixing at least one impurity with such a metal oxide.

Further, the transparent electrode layer 120 includes at least first transparent electrodes 121 and second transparent electrodes 122, which are separated by patterning or scribing.

The thin film solar cell module 100 in accordance with this embodiment is formed by connecting a plurality of photoelectric conversion units A in series. Therefore, an arbitrary photoelectric conversion unit A including a first transparent electrode 121 and a second transparent electrode 122 will be described below for convenience of understanding.

With reference to FIG. 1, the photoelectric conversion layers 170 are provided on the patterned transparent electrode layer 120, i.e., the first transparent electrode 121 and the second transparent electrode 122, and are formed in a triple or more structure including at least the first photoelectric conversion layer 130, the second photoelectric conversion layer 140 and the third photoelectric conversion layer 150.

The first photoelectric conversion layer 130 may include a P-type semiconductor layer formed of amorphous silicon (a-Si), an intrinsic semiconductor layer and an N-type semiconductor layer. The second photoelectric conversion layer 140 may include a P-type semiconductor layer formed of amorphous silicon-germanium (a-Si:Ge), an intrinsic semiconductor layer and an N-type semiconductor layer. The third photoelectric conversion layer 150 may include a P-type semiconductor layer formed of microcrystalline silicon (μc-Si) or microcrystalline silicon-germanium (μc-Si:Ge), an intrinsic semiconductor layer and an N-type semiconductor layer. Respective photoelectric conversion layers 130, 140 and 150 may be formed of respective semiconductors.

Thereby, the first photoelectric conversion layer 130, the second photoelectric conversion layer 140 and the third photoelectric conversion layer 150 may have different bandgap energies. As wavelength bands of light, such as sunlight absorbed by the first photoelectric conversion layer 130, the second photoelectric conversion layer 140 and the third photoelectric conversion layer 150 are different, the thin film solar cell module 100 more effectively absorbs various wavelength bands of sunlight.

Further, the photoelectric conversion layers 170 include at least one of a first intermediate layer 135 formed between the first photoelectric conversion layer 130 and the second photoelectric conversion layer 140 and a second intermediate layer 145 formed between the second photoelectric conversion layer 140 and the third photoelectric conversion layer 150. Although FIG. 1, for example, illustrates the photoelectric conversion layers 170 as including both the first intermediate layer 135 and the second intermediate layer 145, the structure of the photoelectric conversion layers 170 is not limited thereto.

The first intermediate layer 135 and the second intermediate layer 145 may be formed of at least one selected from among transparent conductive oxides (TCOs), for example, light transmitting metal oxides, such as tin oxide (SnO₂), zinc oxide (ZnO) and indium tin oxide (ITO), or may be formed of a mixture obtained by mixing at least one impurity with such a metal oxide.

The first intermediate layer 135 and the second intermediate layer 145 reflect incident light, thus improving light absorption ratios of the first photoelectric conversion layer 130 and the second photoelectric conversion layer 140. Thereby, the first photoelectric conversion layer 130 and the second photoelectric conversion layer 140 may be respectively formed to a thinner or thin thickness.

The first intermediate layer 135 is cut by a first cutting groove 137, and the second intermediate layer 145 is cut by a second cutting groove 147.

The first cutting groove 137 cuts the first intermediate layer 135 and is extended to an upper surface of the second transparent electrode 122. The first cutting groove 137 is filled with the second photoelectric conversion layer 140.

By filling the first cutting groove 137 with the second photoelectric conversion layer 140 in such a manner, internal shorts occurring due to direct electrical contact between the first intermediate layer 135 belonging to an effective area C1 of the photoelectric conversion unit A and the rear electrode 160 may be prevented.

Further, although conductive materials of the first intermediate layer 135 are re-deposited on the side surface of the first photoelectric conversion layer 130 and thus form a shunt resistance path during a first P2 scribing process to form the first cutting groove 137, the first cutting groove 137 belongs to an ineffective area C2 and silicon forming the second photoelectric conversion layer 140 has high resistance, and thus a current flow through the shunt resistance path may be blocked. In embodiments of the present invention, reference to an effective area C1 refers to areas where various cuts are not formed or lacking, and reference to an ineffective area C2 refers to areas where various cuts are formed or included.

The second cutting groove 147 cuts the second intermediate layer 145 at a position differing from the first cutting groove 137 and is extended to the upper surface of the second transparent electrode 122.

The second cutting groove 147 is filled with the third photoelectric conversion layer 150. Thereby, internal shorts occurring due to direct electrical contact between the second intermediate layer 145 belonging to the effective area C1 of the photoelectric conversion unit A and the rear electrode 160 may be prevented. Further, a current flow through a shunt resistance path, which is formed during formation of the second cutting groove 147, may be blocked, thereby reducing or preventing reduction of a fill factor.

The third photoelectric conversion layer 150 is cut by a third cutting groove 157 formed at a position differing from the first cutting groove 137 and the second cutting groove 147, is extended to the upper surface of the second transparent electrode 122, and is filled with the rear electrode 160.

A rear reflective layer may be formed between the photoelectric conversion layer 150 and the rear electrode 160. The rear reflective layer reflects incident light and thus improves photoelectric conversion efficiency of the third photoelectric conversion layer 150. If the rear reflective layer is formed, the third cutting groove 157 may cut both the third photoelectric conversion layer 150 and the rear reflective layer.

The rear electrode 160 may be formed of one selected from metals having excellent electrical conductivity, such as gold (Au), silver (Ag) and aluminum (Al), and fill the third cutting groove 157, to be thus directly connected to the second transparent electrode 122. Thereby, the above-described first photoelectric conversion layer 130, second photoelectric conversion layer 140 and third photoelectric conversion layer 150 are connected in series.

Further, the rear electrode 160 is cut by a fourth cutting groove 167 formed at a position differing from the first, second and third cutting grooves 137, 147 and 157, and the fourth cutting groove 167 is extended to the upper surface of the second transparent electrode 122, thereby forming a photoelectric conversion unit A. A plurality of photoelectric conversion units may be formed by a plurality of fourth cutting grooves 167. The fourth cutting groove 167 is filled with air, thereby forming an insulating layer between the neighboring photoelectric conversion units A. The fourth cutting grooves 167 may be filled with another gas or material.

The above-descried first transparent electrode 121 may serve as the second transparent electrode 122 of a neighboring photoelectric conversion unit A and the above-described second transparent electrode 122 may serve as the first transparent electrode 121 of another neighboring photoelectric conversion unit A, and the plural photoelectric conversion units A may be connected in series.

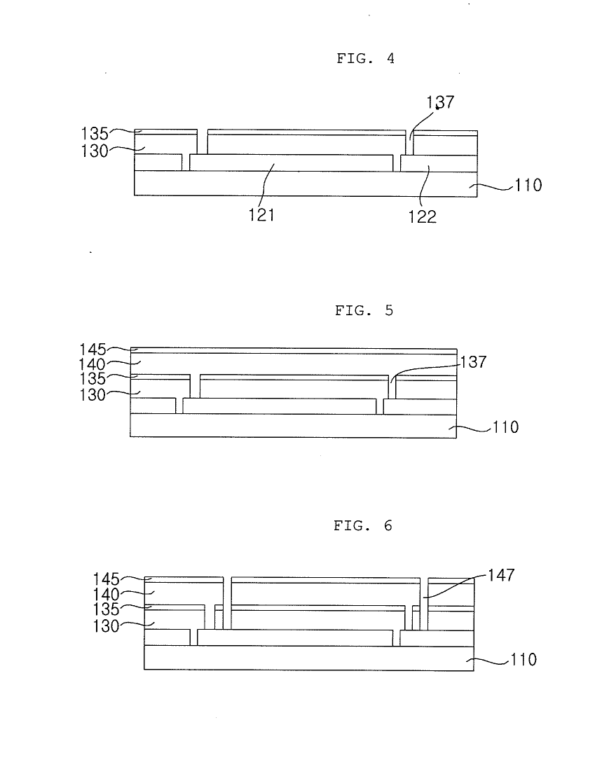

FIGS. 2 to 9 are views illustrating a fabricating method of the thin film solar cell module of FIG. 1.

With reference to FIGS. 2 to 9, the fabricating method of the thin film solar cell module 100 will be described. First, as shown in FIG. 2, the transparent electrode layer 120 is deposited on an entire surface of the substrate 110 and is then patterned, thereby forming the first electrodes 121 and the second electrodes 122.

The transparent electrode layer 120 may be formed through heat treatment of a conductive transparent electrode formation paste on the substrate 110, a deposition method using a sputtering process or a plating method.

The transparent electrode layer 120 may be formed of at least one selected from among metal oxides, for example, tin oxide (SnO₂), zinc oxide (ZnO) and indium tin oxide (ITO), or may be formed of a mixture obtained by mixing at least one impurity with such a metal oxide.

Patterning of the transparent electrode layer 120 may be carried out through a P1 scribing process. The P1 scribing process is a process in which a laser is irradiated from the bottom onto the substrate 110 to evaporate the transparent electrode layer 120 located at some regions. Thereby, the transparent electrode layer 120 includes at least the first transparent electrode 121 and the second transparent electrode 122 separated from each other by a distance, which may be regular.

Thereafter, as shown in FIGS. 3 to 8, the photoelectric conversion layers 170 are formed on the first transparent electrode 121 and the second transparent electrode 122, and are then patterned.

The photoelectric conversion layers 170 are formed in a triple or more structure including at least the first photoelectric conversion layer 130, the second photoelectric conversion layer 140 and the third photoelectric conversion layer 150. Further, the photoelectric conversion layers 170 includes at least one of the first intermediate layer 135 formed between the first photoelectric conversion layer 130 and the second photoelectric conversion layer 140 and the second intermediate layer 145 formed between the second photoelectric conversion layer 140 and the third photoelectric conversion layer 150.

Although this embodiment illustrates the photoelectric conversion layers 170 formed in the triple structure in which both the first intermediate layer 135 and the second intermediate layer 145 are formed, the triple structure of the photoelectric conversion layers 170 is not limited thereto. In the fabricating method, as described below, formation of the first intermediate layer 135 or formation of the second intermediate layer 145 may be omitted in other embodiments.

With reference to FIGS. 3 and 4, the first photoelectric conversion layer 130 and the first intermediate layer 135 are deposited on the first transparent electrode 121 and the second transparent electrode 122 through CVD, such as PECVD, and then the deposited first photoelectric conversion layer 130 and first intermediate layer 135 are patterned, thereby forming the first cutting groove 137.

The first photoelectric conversion layer 130 has a p-i-n structure including amorphous silicon (a-Si), and when the first photoelectric conversion layer 130 is deposited, the first photoelectric conversion layer 130 also fills a space between the first transparent electrode 121 and the second transparent electrode 122.

The first intermediate layer 135 may be formed of a TCO-based material in the same manner as the transparent electrode layer 120, and reflects incident sunlight so that the reflected sunlight is incident back upon the first photoelectric conversion layer 130. Therefore, efficiency of the first photoelectric conversion layer 130 is improved.

The first cutting groove 137 is formed through the first P2 scribing process and is extended to the upper surface of the second transparent electrode 122. An output of a laser used in the first P2 scribing process is lower than an output of the laser used in the P1 scribing process.

Therefore, when the laser is irradiated from the bottom onto the substrate 110 so as to carry out the first P2 scribing process, the second transparent electrode 122 is not evaporated but the first photoelectric conversion layer 130 and the first intermediate layer 135 on the second transparent electrode 122 are selectively evaporated and thus removed. In an embodiment of the present invention, the first cutting groove 137 is formed only through the first photoelectric conversion layer 130 and the first intermediate layer 135 at a particular location.

If the first intermediate layer 135 is omitted, the second photoelectric conversion layer 140 is formed directly on the first photoelectric conversion layer 130 and formation of the first cutting groove 137 is also omitted.

Thereafter, as shown in FIGS. 5 and 6, the second photoelectric conversion layer 140 and the second intermediate layer 145 are deposited and are then patterned, thereby forming the second cutting groove 147.

The second photoelectric conversion layer 140 has a p-i-n structure including amorphous silicon-germanium (a-Si:Ge), and fills the first cutting groove 137.

Therefore, internal shorts occurring due to direct electrical contact between the first intermediate layer 135 and the rear electrode 160, which will be described later, is prevented. Further, since the second photoelectric conversion layer 140 has a greater resistance than the first intermediate layer 135, although conductive materials of the first intermediate layer 135 are re-deposited on the side surface of the first photoelectric conversion layer 130 and thus form a shunt resistance path when the first cutting groove 137 is formed, a current flow through the shunt resistance path is blocked.

The second cutting groove 147 is formed through a second P2 scribing process, is located at a position differing from the first cutting groove 137 and is extended to the upper surface of the second transparent electrode 122. An output of a laser used in the second P2 scribing process is lower than an output of the laser used in the P1 scribing process, and thus the second transparent electrode 122 is not evaporated. In an embodiment of the present invention, the second cutting groove 147 is formed only through the first photoelectric conversion layer 130, the first intermediate layer 135, the second photoelectric conversion layer 140 and the second intermediate layer 145 at a particular location.

If the second intermediate layer 145 is omitted, the third photoelectric conversion layer 150 is formed directly on the second photoelectric conversion layer 140 and formation of the second cutting groove 147 is also omitted.

Thereafter, as shown in FIGS. 7 and 8, the third photoelectric conversion layer 150 is deposited and is then patterned, thereby forming the third cutting groove 157.

The third photoelectric conversion layer 150 has a p-i-n structure including microcrystalline silicon (μc-Si) or microcrystalline silicon-germanium (μc-Si:Ge), and fills the second cutting groove 147.

Therefore, direct electrical contact between the second intermediate layer 145 and the rear electrode 160 is prevented, and a current flow through a shunt resistance path formed on the side surface of the second intermediate layer 145 is blocked, thereby reducing or preventing reduction of a fill factor.

The third cutting groove 157 is formed through a third P2 scribing process, is located at a position differing from the above-described first cutting groove 137 and second cutting groove 147 and is extended to the upper surface of the second transparent electrode 122.

Further, an output of a laser used in the third P2 scribing process is lower than an output of the laser used in the P1 scribing process, and thus the second transparent electrode 122 is not evaporated when the laser is irradiated from the bottom onto the substrate 110. In an embodiment of the present invention, the third cutting groove 157 is formed only through the first photoelectric conversion layer 130, the first intermediate layer 135, the second photoelectric conversion layer 140, the second intermediate layer 145, and the third photoelectric conversion layer 150 at a particular location.

A rear reflective layer to improve photoelectric conversion efficiency of the third photoelectric conversion layer 150 may be formed on the third photoelectric conversion layer 150. In this instance, the rear reflective layer as well as the third cutting groove 157 may be cut by the third cutting groove 157.

Thereafter, as shown in FIG. 9, the rear electrode 160 is formed on the third photoelectric conversion layer 150 and is then patterned, thereby forming the fourth cutting groove 167.

The rear electrode 160 may be formed of a conductive metal, and may be formed of one selected from various materials according to formation methods thereof.

For example, if the rear electrode 160 is formed through a screen printing method, the rear electrode 160 may be formed of one selected from the group consisting of silver (Ag), aluminum (Al) and a combination thereof, and if the rear electrode 160 is formed through an inkjet method or a dispensing method, the rear electrode 160 may be formed of one selected from the group consisting of nickel (Ni), silver (Ag) and a combination thereof. Other materials or metals may be used.

Further, if the rear electrode 160 is formed through a plating method, the rear electrode 160 may be formed of one selected from the group consisting of nickel (Ni), copper (Cu), silver (Ag) and combinations thereof, and if the rear electrode 160 is formed through a deposition method, the rear electrode 160 may be formed of one selected from the group consisting of aluminum (Al), nickel (Ni), copper (Cu), silver (Ag), titanium (Ti), lead (Pb), chrome (Cr), tungsten (W) and combinations thereof. Other materials or metals may be used.

Further, with respect to the rear electrode 160 being formed through the screen printing method, the rear electrode 160 may be formed of a mixture of aluminum (Al) and a conductive polymer.

The rear electrode 160 fills the third cutting groove 157 and is directly connected to the second transparent electrode 122. Thereby, the first photoelectric conversion layer 130, the second photoelectric conversion layer 140 and the third photoelectric conversion layer 150 are connected in series.

The fourth cutting groove 167 is formed through a P3 scribing process. That is, the fourth cutting groove 167 is formed by irradiating a laser from the bottom onto the substrate 110, and the fourth cutting groove 167 is extended to the upper surface of the second transparent electrode 122. In an embodiment of the present invention, the fourth cutting groove 167 is formed only through the first photoelectric conversion layer 130, the first intermediate layer 135, the second photoelectric conversion layer 140, the second intermediate layer 145, the third photoelectric conversion layer 150 and the rear electrode at a particular location.

The fourth cutting groove 167 is filled with air, thereby forming an insulating layer and thus connecting neighboring photoelectric conversion units in series.

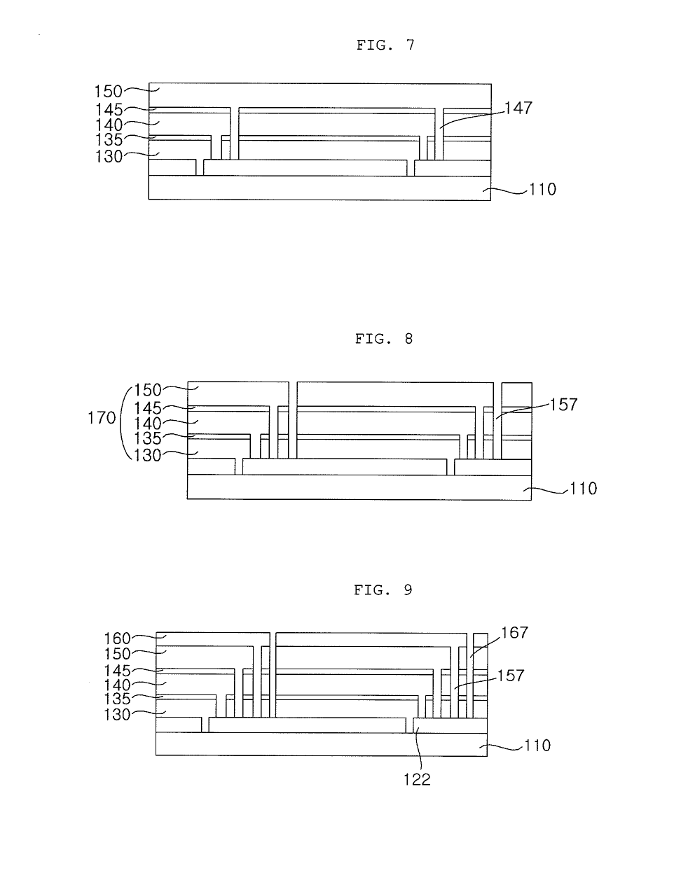

FIG. 10 is a cross-sectional view of a thin film solar cell module in accordance with another embodiment of the present invention.

With reference to FIG. 10, a thin film solar cell module 200 in accordance with this embodiment of the present invention includes a front substrate 210 upon which sunlight is incident, a transparent electrode layer 220 patterned on the front substrate 210, photoelectric conversion layers 270 located on the transparent electrode layer 220 and including at least a first photoelectric conversion layer 230, a second photoelectric conversion layer 240 and a third photoelectric conversion layer 250, and a rear electrode 260 provided on the photoelectric conversion layers 270.

Further, the photoelectric conversion layers 270 include at least one of a third intermediate layer 235 formed between the first photoelectric conversion layer 230 and the second photoelectric conversion layer 240 and a fourth intermediate layer 245 formed between the second photoelectric conversion layer 240 and the third photoelectric conversion layer 250. Although FIG. 10 illustrates the photoelectric conversion layers 270 as including both the third intermediate layer 235 and the fourth intermediate layer 245, but the structure of the photoelectric conversion layers 270 is not limited thereto.

The front substrate 210, the transparent electrode layer 220, the photoelectric conversion layers 270 and the rear electrode 260 in this embodiment are substantially the same as those in the former embodiment shown in FIG. 1, and a detailed description thereof will thus be omitted.

The third intermediate layer 235 and the fourth intermediate layer 245 may include silicon oxide (SiOₓ). Silicon oxide forming the third intermediate layer 235 and the fourth intermediate layer 245 is substantially the same as silicon forming the photoelectric conversion layers 270, and thus adhesive force of the third intermediate layer 235 and the fourth intermediate layer 245 is improved.

As described above, the first photoelectric conversion layer 230 may be formed of amorphous silicon (a-Si), the second photoelectric conversion layer 240 may be formed of amorphous silicon-germanium (a-Si:Ge), and the third photoelectric conversion layer 250 may be formed of microcrystalline silicon (μc-Si) or microcrystalline silicon-germanium (μc-Si:Ge).

Thereby, for example, the third intermediate layer 235 may be formed of amorphous silicon oxide which is similar to the material of the first photoelectric conversion layer 230 and the fourth intermediate layer 245 may be formed of amorphous silicon oxide doped with germanium (Ge) which is similar to the material of the second photoelectric conversion layer 240, and thus adhesive force of the third intermediate layer 235 and the fourth intermediate layer 245 is improved.

Further, the third intermediate layer 235 and the fourth intermediate layer 245 are doped with N-type or P-type impurities, thus having improved electrical conductivity.

The third intermediate layer 235 and the fourth intermediate layer 245 reflect incident light or reflect selective wavelength bands of the incident light, thus improving light absorption ratios of the first photoelectric conversion layer 230 and the second photoelectric conversion layer 240.

The photoelectric conversion layers 270 are divided once by first cutting grooves 257, the first cutting grooves 257 are extended to the upper surface of the transparent electrode layer 220, and the rear electrode 260 fills the first cutting grooves 257 and is thus electrically connected to the transparent electrode layer 220.

That is, since the third intermediate layer 235 and the fourth intermediate layer 245 are not formed of conductive materials, although the third intermediate layer 235 and the fourth intermediate layer 245 directly contact the rear electrode 260, internal shorts do not occur. Therefore, cutting grooves to cut the third intermediate layer 235 and the fourth intermediate layer 245 may be omitted.

Further, although a scribing process to foam the fifth cutting grooves 257 is carried out, a shunt resistance path due to re-deposition of conductive materials is not formed. Therefore, the thin film solar cell module 200 in accordance with this embodiment of the present invention prevents internal shorts and blocks a current flow through the shunt resistance path, thereby reducing or preventing reduction of a fill factor.

The rear electrode 260 is cut by sixth cutting grooves 267, and the sixth cutting grooves 267 are filled with air, thereby forming an insulating layer. Other gas or material may be filled therein.

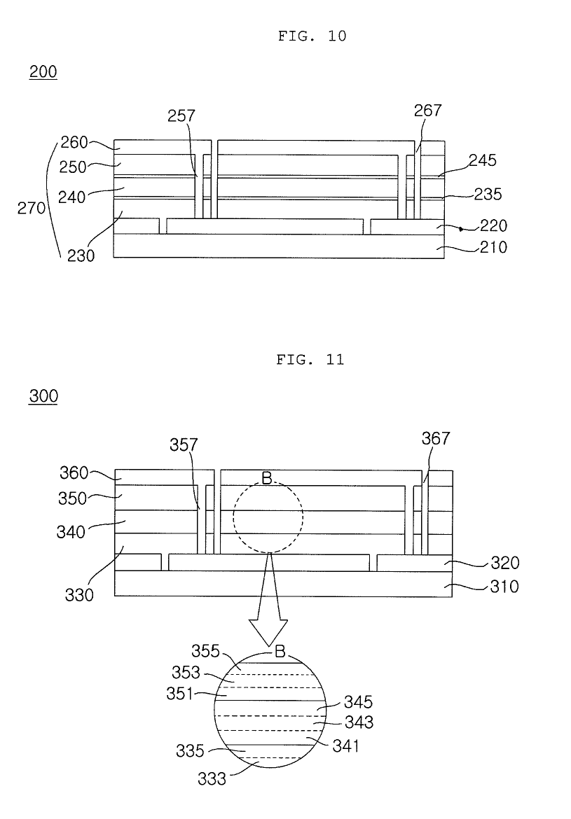

FIG. 11 is a cross-sectional view of a thin film solar cell module in accordance with a further embodiment of the present invention.

With reference to FIG. 11, a thin film solar cell module 300 in accordance with this embodiment of the present invention includes a substrate 310, a transparent electrode layer 320 provided on the substrate 210, a first photoelectric conversion layer 330, a second photoelectric conversion layer 340 and a third photoelectric conversion layer 350 sequentially stacked on the transparent electrode layer 320, and a rear electrode 360 provided on the third photoelectric conversion layer 350. The first photoelectric conversion layer 330, the second photoelectric conversion layer 340 and the third photoelectric conversion layer 350 are cut by seventh cutting grooves 357, and the rear electrode 360 fills the seventh cutting grooves 357 and is thus electrically connected to the transparent electrode layer 230.

The substrate 310, the transparent electrode layer 320 and the rear electrode 360 in this embodiment are substantially the same as those in the former embodiment shown in FIG. 1, and a detailed description thereof will thus be omitted.

With reference to the portion B of FIG. 11, the first photoelectric conversion layer 330 may include a P-type semiconductor layer formed of amorphous silicon (a-Si), an intrinsic semiconductor layer 333 and an N-type semiconductor layer 335. The intrinsic semiconductor layer 333 reduces a re-coupling rate of carriers and serves to absorb light, and the P-type semiconductor layer and the N-type semiconductor layer 335 are doped with different kinds of impurities and thus collect electrons and holes generated by the intrinsic semiconductor layer 333.

In the same manner, the second photoelectric conversion layer 330 may include a P-type semiconductor layer 341 formed of amorphous silicon-germanium (a-Si:Ge), an intrinsic semiconductor layer 343 and an N-type semiconductor layer 345. The third photoelectric conversion layer 350 may include a P-type semiconductor layer 351 formed of microcrystalline silicon (μc-Si) or microcrystalline silicon-germanium (μc-Si:Ge), an intrinsic semiconductor layer 353 and an N-type semiconductor layer 355.

Thereby, since the first photoelectric conversion layer 330, the second photoelectric conversion layer 340 and the third photoelectric conversion layer 350 have different bandgap energies, wavelength bands of sunlight absorbed by the first photoelectric conversion layer 330, the second photoelectric conversion layer 340 and the third photoelectric conversion layer 350 are different, and thus the thin film solar cell module 300 more effectively absorbs sunlight.

Further, an index of refraction of the intrinsic semiconductor layer 333 of the first photoelectric conversion layer 330 may be higher than an index of refraction of the N-type semiconductor layer 335 of the first photoelectric conversion layer 330, or the index of refraction of the N-type semiconductor layer 335 of the first photoelectric conversion layer 330 may be higher than an index of refraction of the P-type semiconductor layer 341 of the second photoelectric conversion layer 340.

According to Snell's law, when light is incident from a material having a high index of refraction upon a material having a low index of refraction, if an angle of incidence is greater than a critical angle, the entirety of the light is reflected by an interface between the two materials having different indexes of refraction.

Therefore, when the index of refraction of the intrinsic semiconductor layer 333 of the first photoelectric conversion layer 330 is higher than the index of refraction of the N-type semiconductor layer 335 of the first photoelectric conversion layer 330 or the index of refraction of the N-type semiconductor layer 335 of the first photoelectric conversion layer 330 is higher than the index of refraction of the P-type semiconductor layer 341 of the second photoelectric conversion layer 340, light having passed through the intrinsic semiconductor layer 333 of the first photoelectric conversion layer 330 is reflected by the N-type semiconductor layer 335 of the first photoelectric conversion layer 330 or the P-type semiconductor layer 341 of the second photoelectric conversion layer 340 and is then re-incident upon the intrinsic semiconductor layer 333 of the first photoelectric conversion layer 330, thereby improving photoelectric conversion efficiency of the first photoelectric conversion layer 330.

In the same manner, an index of refraction of the intrinsic semiconductor layer 343 of the second photoelectric conversion layer 340 may be higher than an index of refraction of the N-type semiconductor layer 345 of the second photoelectric conversion layer 340, or the index of refraction of the N-type semiconductor layer 345 of the second photoelectric conversion layer 340 may be higher than an index of refraction of the P-type semiconductor layer 351 of the third photoelectric conversion layer 350, thereby improving photoelectric conversion efficiency of the second photoelectric conversion layer 340.

That is, in accordance with the present invention, the N-type semiconductor layer 335 of the first photoelectric conversion layer 330 or the P-type semiconductor layer 341 of the second photoelectric conversion layer 430 functions as the first intermediate layer 135 of FIG. 1, and the N-type semiconductor layer 345 of the second photoelectric conversion layer 340 or the P-type semiconductor layer 351 of the third photoelectric conversion layer 350 functions as the second intermediate layer 135 of FIG. 1.

Since the N-type semiconductor layer 335 of the first photoelectric conversion layer 330, the P-type semiconductor layer 341 of the second photoelectric conversion layer 340, the N-type semiconductor layer 345 of the second photoelectric conversion layer 340 and the P-type semiconductor layer 351 of the third photoelectric conversion layer 350 are not formed of conductive materials, although the N-type semiconductor layer 335, the P-type semiconductor layer 341, the N-type semiconductor layer 345 and the P-type semiconductor layer 351 directly contact the rear electrode 360, internal shorts do not occur.

Further, although a scribing process to form the seventh cutting grooves 357 is carried out, a shunt resistance path due to re-deposition of conductive materials is not formed.

Therefore, the thin film solar cell module 300 in accordance with this embodiment of the present invention prevents internal shorts and blocks a current flow through the shunt resistance path, thereby reducing or preventing reduction of a fill factor.

The rear electrode 360 is cut by eighth cutting grooves 367, and the eighth cutting grooves 367 are filled with air, thereby forming an insulating layer. Other gas or material may be filled therein.

As apparent from the above description, a thin film solar cell module having a triple or more structure in accordance with embodiments of the present invention prevent internal shorts.

Further, the thin film solar cell module reduces or prevents reduction of a fill factor due to shunt resistance, which may be generated during a scribing process.

Although the embodiments of the present invention have been disclosed for illustrative purposes, those skilled in the art will appreciate that various modifications and applications are possible, without departing from the scope and spirit of the invention as disclosed in the accompanying claims. For example, the respective elements described in detail in the embodiments may be modified. Further, it will be understood that differences relating to such modifications and applications are within the scope of the invention defined in the accompanying claims.

What is claimed is:

1. A thin film solar cell module comprising:
a front substrate;
a transparent electrode layer patterned on the front substrate to have at least first transparent electrodes and second transparent electrodes;
photoelectric conversion layers provided on the transparent electrode layer and including at least a first photoelectric conversion layer, a second photoelectric conversion layer and a third photoelectric conversion layer; and
a rear electrode provided on the photoelectric conversion layers,
wherein the photoelectric conversion layers further include at least one of a first intermediate layer provided between the first photoelectric conversion layer and the second photoelectric conversion layer, cut by first cutting grooves, and a second intermediate layer provided between the second photoelectric conversion layer and the third photoelectric conversion layer, cut by second cutting grooves, and
the first intermediate layer and the second intermediate layer are respectively formed of a transparent conductive oxide (TCO).

2. The thin film solar cell module according to claim 1, wherein the first cutting grooves and the second cutting grooves are extended to an upper surface of the transparent electrode layer at different positions in the photoelectric conversion layers, and
the second photoelectric conversion layer fills the first cutting grooves and the third photoelectric conversion layer fills the second cutting grooves.

3. The thin film solar cell module according to claim 2, wherein the third photoelectric conversion layer is cut by third cutting grooves extended to the upper surface of the transparent electrode layer at positions differing from the first cutting grooves and the second cutting grooves in the photoelectric conversion layers, and
the rear electrode fills the third cutting grooves so as to be connected to the transparent electrode layer.

4. The thin film solar cell module according to claim 3, wherein the rear electrode is cut by fourth cutting grooves at positions differing from the first cutting grooves to the third cutting grooves in the photoelectric conversion layers, and
the fourth cutting grooves are extended to the upper surface of the transparent electrode layer so as to form an insulating layer.

5. The thin film solar cell module according to claim 1, wherein the first photoelectric conversion layer is formed of amorphous silicon (a-Si).

6. The thin film solar cell module according to claim 1, wherein the second photoelectric conversion layer is formed of amorphous silicon-germanium (a-Si:Ge).

7. The thin film solar cell module according to claim 1, wherein the third photoelectric conversion layer is formed of microcrystalline silicon (μc-Si) or microcrystalline silicon-germanium (μc-Si:Ge).

8. The thin film solar cell module according to claim 1, wherein the TCO is one selected from the group consisting of tin oxide (SnO₂), zinc oxide (ZnO) and indium tin oxide (ITO).

9. A fabricating method of a thin film solar cell module comprising:
forming a transparent electrode layer on a substrate and then patterning the transparent electrode layer to have at least first transparent electrodes and second transparent electrodes;
forming photoelectric conversion layers, including at least a first photoelectric conversion layer, a second photoelectric conversion layer and a third photoelectric conversion layer, on the first transparent electrodes and the second transparent electrodes and then patterning the photoelectric conversion layers; and
forming a rear electrode on the photoelectric conversion layers and then patterning the rear electrode,
wherein the forming and patterning of the photoelectric conversion layers include at least one of forming first cutting grooves by forming a first intermediate layer on the first photoelectric conversion layer and then patterning the first intermediate layer, and forming second cutting grooves by forming a second intermediate layer on the second photoelectric conversion layer and then patterning the second intermediate layer, and
the first intermediate layer and the second intermediate layer are respectively formed of a transparent conductive oxide (TCO), and the first cutting grooves and the second cutting grooves are extended to an upper surface of the second transparent electrodes at different positions in the photoelectric conversion layers.

10. The fabricating method according to claim 9, wherein the forming and patterning of the photoelectric conversion layers further include forming third cutting grooves by patterning the third photoelectric conversion layer, and
the first cutting grooves, the second cutting grooves and the third cutting grooves are extended to the upper surface of the second transparent electrodes at different positions in the photoelectric conversion layers.

11. The fabricating method according to claim 10, wherein the forming and patterning of the rear electrode include forming fourth cutting grooves by forming the rear electrode on the third cutting grooves and the third photoelectric conversion layer, and then patterning the rear electrode on the third photoelectric conversion layer, and
the first cutting grooves to the fourth cutting grooves are extended to the upper surface of the second transparent electrodes at different positions in the photoelectric conversion layers.

12. The fabricating method according to claim 11, wherein each of the first cutting grooves to the fourth cutting grooves is formed by a respective laser scribing process.

13. A thin film solar cell module comprising:
a front substrate;
a transparent electrode layer patterned on the front substrate;
photoelectric conversion layers provided on the transparent electrode layer, and including at least a first photoelectric conversion layer, a second photoelectric conversion layer and a third photoelectric conversion layer;
cutting grooves formed entirely through the photoelectric conversion layers and extending to an upper surface of the transparent electrode layer to divide the photoelectric conversion layers; and
a rear electrode provided on the upper surface of the photoelectric conversion layers so as to fill the cutting grooves.

14. The thin film solar cell module according to claim 13, wherein the photoelectric conversion layers further include at least one of a first intermediate layer provided between the first photoelectric conversion layer and the second photoelectric conversion layer, and a second intermediate layer provided between the second photoelectric conversion layer and the third photoelectric conversion layer, and
the first intermediate layer and the second intermediate layer include silicon oxide (SiOₓ).

15. The thin film solar cell module according to claim 13, wherein the first photoelectric conversion layer is formed of amorphous silicon (a-Si), the second photoelectric conversion layer is formed of amorphous silicon-germanium (a-Si:Ge), and the third photoelectric conversion layer is formed of microcrystalline silicon (μc-Si) or microcrystalline silicon-germanium (μc-Si:Ge), and
the first intermediate layer is formed of amorphous silicon oxide and the second intermediate layer is formed of amorphous silicon oxide doped with germanium.

16. The thin film solar cell module according to claim 13, wherein the first intermediate layer and the second intermediate layer are doped with impurities.

17. The thin film solar cell module according to claim 13, wherein the first photoelectric conversion layer directly contacts the second photoelectric conversion layer, and the second photoelectric conversion layer directly contacts the third photoelectric conversion layer.

18. The thin film solar cell module according to claim 13, wherein the first photoelectric conversion layer includes amorphous silicon (a-Si), the second photoelectric conversion layer includes amorphous silicon-germanium (a-Si:Ge), and the third photoelectric conversion layer includes microcrystalline silicon (μc-Si) or microcrystalline silicon-germanium (μc-Si:Ge).

19. The thin film solar cell module according to claim 18, wherein the first photoelectric conversion layer includes a first P-type semiconductor layer of the amorphous silicon (a-Si), a first intrinsic semiconductor layer and a first N-type semiconductor layer,
the second photoelectric conversion layer includes a second P-type semiconductor layer of the amorphous silicon-germanium (a-Si:Ge), a second intrinsic semiconductor layer and a second N-type semiconductor layer, and
the third photoelectric conversion layer includes a third P-type semiconductor layer of the microcrystalline silicon (μc-Si) or the microcrystalline silicon-germanium (μc-Si:Ge), a third intrinsic semiconductor layer and a third N-type semiconductor layer.

20. The thin film solar cell module according to claim 13, wherein an index of refraction of at least one layer of the first photoelectric conversion layer is higher than an index of refraction of at least one layer of the second photoelectric conversion layer.
